(19) United States
(12) Patent Application Publication
(10) Pub. No.: US 2026/0101811 A1
(43) Pub. Date: Apr. 9, 2026

(54) SEMICONDUCTOR DEVICE WITH DAM STRUCTURE COVERING SLOT OF SUBSTRATE

(71) Applicant: NANYA TECHNOLOGY CORPORATION, NEW TAIPEI CITY (TW)

(72) Inventor: WU-DER YANG, NEW TAIPEI CITY (TW)

(21) Appl. No.: 18/945,885

(22) Filed: Nov. 13, 2024

Related U.S. Application Data
(62) Division of application No. 18/909,144, filed on Oct. 8, 2024.

(51) Int. Cl. H01L 23/16; H01L 21/48; H01L 21/56; H01L 23/00; H01L 23/31; H01L 23/498

(52) U.S. Cl. CPC H10W 76/40; H10W 70/093; H10W 74/016; H10W 74/117; H10W 90/401; H10W 90/701; H10W 90/754

(57) ABSTRACT

A semiconductor device and method for manufacturing the same are provided. The semiconductor device includes a substrate, an electronic component, an encapsulant, and a dam structure. The substrate has a lower surface and an upper surface opposite to the first surface. The electronic component is disposed on the upper surface of the substrate. The encapsulant is disposed on the upper surface of the substrate and has a portion penetrating the substrate. The dam structure vertically overlaps the portion of the encapsulant.

### CROSS-REFERENCE TO RELATED APPLICATION

This application is a divisional application of U.S. Non-Provisional Application Ser. No. 18/909,144 filed Oct. 8, 2024, which is incorporated herein by reference in its entirety.

### TECHNICAL FIELD

The present disclosure relates to a semiconductor device and a method for manufacturing the same, and more particularly, to a semiconductor device including a dam structure covering a slot of a substrate.

### DISCUSSION OF THE BACKGROUND

With the rapid growth of the electronics industry, integrated circuits (ICs) have achieved high performance and miniaturization. Technological advances in IC materials and design have produced generations of ICs in which each successive generation has smaller and more complex circuits.

Many techniques have been developed to increase the performance of semiconductor devices. For example, a decoupling capacitor structure may be utilized to filter signals with a specific frequency. However, such decoupling capacitor structures may occupy additional areas, which increases the size of a semiconductor device. Therefore, improved semiconductor devices and methods of solving such problems are required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, an electronic component, an encapsulant, and a dam structure. The substrate has a lower surface and an upper surface opposite to the first surface. The electronic component is disposed on the upper surface of the substrate. The encapsulant is disposed on the upper surface of the substrate and has a portion penetrating the substrate. The dam structure vertically overlaps the portion of the encapsulant.

Another aspect of the present disclosure provides another semiconductor device. The semiconductor device includes a substrate, an electronic component, an encapsulant, and a dam structure. The substrate has a lower surface and an upper surface opposite to the first surface. The electronic component is disposed on the upper surface of the substrate. The encapsulant is disposed on the upper surface of the substrate and has a portion penetrating the substrate. The substrate and the dam structure define an encapsulant-injection slot. A first aperture of the encapsulant-injection slot abutting the upper surface of the substrate is different from a second aperture of the encapsulant-injection slot abutting the lower surface of the substrate.

Another aspect of the present disclosure provides a method of manufacturing a semiconductor device. The method includes: providing a substrate having a lower surface and an upper surface opposite to the first surface, wherein the substrate defines an encapsulant-injection slot penetrating the lower surface and the upper surface; forming an electronic component on the upper surface of the substrate; forming a dam structure on the substrate to reduce an aperture of the encapsulant-injection slot; and forming an encapsulant on the substrate.

When forming an encapsulant on a substrate, a mold chase is used to accommodate a substrate with a slot. Next, a molding material is filled into the mold chase and flows from the upper surface (e.g., the surface on which an electronic component is disposed) to the lower surface of the substrate through the slot. In a comparative device, the molding material may encroach an undesired area of the lower surface of the substrate (e.g., the area on which the solder balls are disposed), which causes a failure of an electrical connection between devices. One of the reasons causing a molding material overflowing is that a slot with a greater aperture, especially a slot with greater dimension along the X direction. In this embodiment, a dam structure is provided to reduce the area (or aperture) of the slot to prevent an undesired region of the substrate from being encroached by the encapsulant. As a result, the issues of the comparative devices can be addressed.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a cross-sectional view along line A-A′ of the semiconductor device as shown in FIG. 1A, in accordance with some embodiments of the present disclosure.

FIG. 1C is a cross-sectional view along line B-B′ of the semiconductor device as shown in FIG. 1A, in accordance with some embodiments of the present disclosure.

FIG. 2A is a top view of a semiconductor device, in accordance with some embodiments of the present disclosure.

FIG. 2B is a cross-sectional view along line C-C′ of the semiconductor device as shown in FIG. 2A, in accordance with some embodiments of the present disclosure.

FIG. 2C is a cross-sectional view along line D-D′ of the semiconductor device as shown in FIG. 2A, in accordance with some embodiments of the present disclosure.

FIG. 3A is a top view of a semiconductor device, in accordance with some embodiments of the present disclosure.

FIG. 3B is a cross-sectional view along line E-E′ of the semiconductor device as shown in FIG. 3A, in accordance with some embodiments of the present disclosure.

FIG. 3C is a cross-sectional view along line F-F′ of the semiconductor device as shown in FIG. 3A, in accordance with some embodiments of the present disclosure.

FIG. 4A is a top view of a semiconductor device, in accordance with some embodiments of the present disclosure.

FIG. 4B is a cross-sectional view along line G-G′ of the semiconductor device as shown in FIG. 4A, in accordance with some embodiments of the present disclosure.

FIG. 4C is a cross-sectional view along line H-H′ of the semiconductor device as shown in FIG. 4A, in accordance with some embodiments of the present disclosure.

FIG. 5 is a flowchart illustrating a method of manufacturing a semiconductor device, in accordance with some embodiments of the present disclosure.

FIG. 6A illustrates one or more stages of an exemplary method for manufacturing a semiconductor device according to some embodiments of the present disclosure.

FIG. 6B is a cross-sectional view along line A-A′ of the stage as shown in FIG. 6A, in accordance with some embodiments of the present disclosure.

FIG. 6C is a cross-sectional view along line B-B′ of the stage as shown in FIG. 6A, in accordance with some embodiments of the present disclosure.

FIG. 7A illustrates one or more stages of an exemplary method for manufacturing a semiconductor device according to some embodiments of the present disclosure.

FIG. 7B is a cross-sectional view along line A-A′ of the stage as shown in FIG. 7A, in accordance with some embodiments of the present disclosure.

FIG. 7C is a cross-sectional view along line B-B′ of the stage as shown in FIG. 7A, in accordance with some embodiments of the present disclosure.

FIG. 8A illustrates one or more stages of an exemplary method for manufacturing a semiconductor device according to some embodiments of the present disclosure.

FIG. 8B is a cross-sectional view along line A-A′ of the stage as shown in FIG. 8A, in accordance with some embodiments of the present disclosure.

FIG. 8C is a cross-sectional view along line B-B′ of the stage as shown in FIG. 8A, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

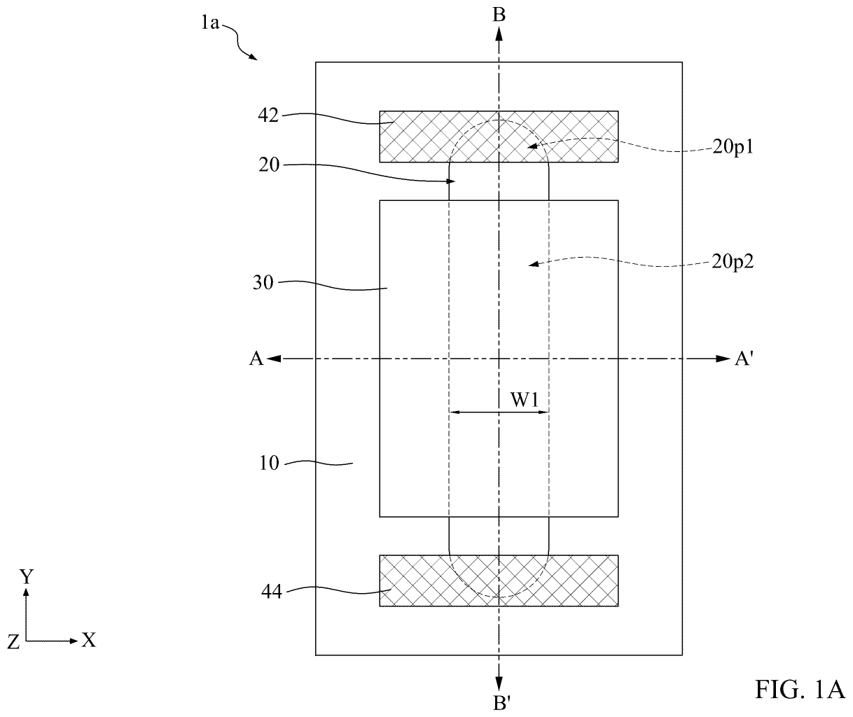

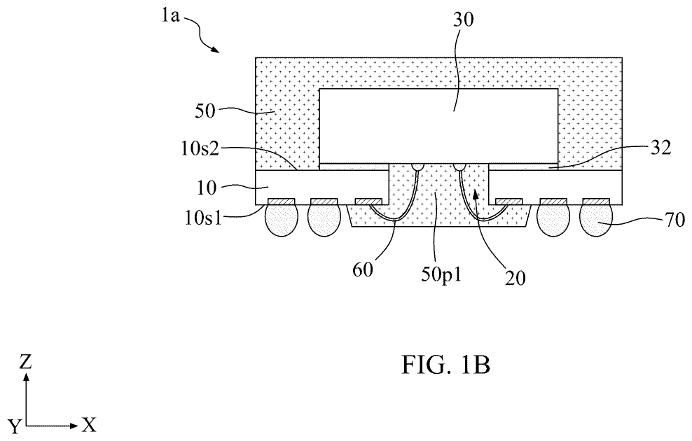

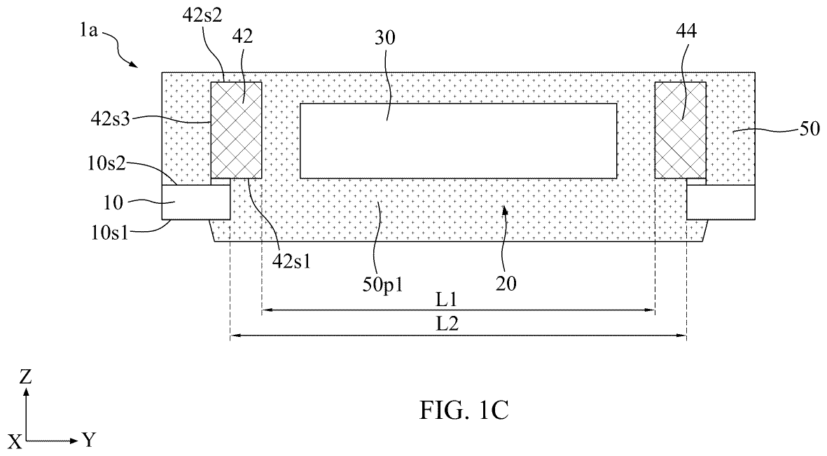

FIG. 1A, FIG. 1B, and FIG. 1C illustrate a semiconductor device 1a, in accordance with some embodiments of the present disclosure. FIG. 1A is a top view. FIG. 1B and FIG. 1C are cross-sectional views along line A-A′ and B-B′ of FIG. 1A, respectively. In some embodiments, the semiconductor device 1a may include a double data rate fifth-generation synchronous dynamic random-access memory (DDR5) or its derivative devices.

In some embodiments, the semiconductor device 1a may include a substrate 10. In some embodiments, the substrate 10 may be or include, for example, a printed circuit board (PCB), such as a paper-based copper foil laminate, a composite copper foil laminate, or a polymer-impregnated glass-fiber-based copper foil laminate.

In some embodiments, the substrate 10 may include a surface 10s1 and a surface 10s2 opposite to the surface 10s1. In some embodiments, the surface 10s1 may also be referred to as a lower surface. In some embodiments, the surface 10s2 may also be referred to as an upper surface.

In some embodiments, the substrate 10 may include conductive pad(s), trace(s), via(s), layer(s), or other interconnection(s) abutting the surfaces 10s1 and 10s2. For example, the substrate 10 may include one or more transmission lines (e.g., communications cables) and one or more grounding lines and/or grounding planes therein.

In some embodiments, the substrate 10 may define an opening 20 (or slot or aperture). The opening 20 may have longer edges extending along the Y direction and shorter edges connecting the longer edges.

As shown in FIG. 1A, the opening 20 may have terminal portions 20p1 on opposite sides of the longer edge. The terminal portion 20p1 may have a curved profile (e.g., semi-sphere profile) or other suitable profiles. The opening 20 may have a central portion 20p2 extending between two terminal portions 20p1. In some embodiments, the central portion 20p2 may have a substantial uniform width along the X direction. In some embodiments, the width W1 of the central portion 20p2 of the opening 20 may be greater than 1100 um, such as 1100 um, 1200 um, 1300 um, 1400 um, 1500 um, or more. In some embodiments, the opening 20 may be configured to allow a molding material (or encapsulant material) to pass through during forming an encapsulant. In some embodiments, the opening 20 may also be referred to as an encapsulant-injection slot.

In some embodiments, the semiconductor device 1a may include an electronic component 30. The electronic component 30 may be disposed on or over the surface 10s2 of the substrate 10. In some embodiments, the electronic component 30 may cover a portion of the opening 20. In some embodiments, the terminal portion 20p1 of the opening 20 may be exposed by the electronic component 30. In some embodiments, a portion of the central portion 20p2 of the opening 20 may be covered by the electronic component 30. In some embodiments, a portion of the central portion 20p2 of the opening 20 may be exposed by the electronic component 30.

The electronic component 30 may include a memory device, such as a dynamic random access memory (DRAM) device, a one-time programming (OTP) memory device, a static random access memory (SRAM) device, or other suitable memory devices. In some embodiments, the electronic component 30 may include a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices), or other devices.

In some embodiments, the electronic component 30 may be attached to the substrate 10 by an adhesive 32. In some embodiments, the adhesive 32 may include a die attach film (DAF) or other suitable materials.

In some embodiments, the electronic component 30 may have an active surface facing the substrate 10 and a passive surface opposite to the active surface. However, the present disclosure is not intended to be limiting.

In some embodiments, the semiconductor device 1a may include a dam structure 42 and a dam structure 44. In some embodiments, the dam structure 42 and dam structure 44 may be disposed on two opposite sides of the electronic component 30. In some embodiments, the dam structure 42 may be disposed on or over the surface 10s2 of the substrate 10. In some embodiments, the dam structure 44 may be disposed on or over the surface 10s2 of the substrate 10. In some embodiments, the dam structure 42 may cover or vertically overlap the terminal portion 20p1 of the opening 20. In some embodiments, the dam structure 44 may cover or vertically overlap the terminal portion 20p1 of the opening 20. The dam structure 42 (or 44) may be attached to the substrate 10 by an adhesive or other suitable materials.

In some embodiments, the dam structure 42 (or dam structure 44) may be configured to reduce the area of the opening 20 through which an encapsulant material passes. In some embodiments, the dam structure 42, dam structure 44, the opening 20, and/or the electronic component 30 may be configured to define an encapsulant-injection slot to allow an encapsulant material pass through. As shown in FIG. 1C, the opening 20 defined by the substrate 10, the electronic component 30, the dam structure 42 and the dam structure 44 may have a first length L1 at the surface 10s2 of the substrate 10 and a second length L2 at the surface 10s2 of the substrate 10 along the Y direction. In some embodiments, the first length L1 may be different from the second length L2. In some embodiments, the first length L1 may be less than the second length L2.

In some embodiments, the dam structure 42 and dam structure 44 may include a dummy die, such as a silicon dummy die, a glass dummy die, a plastic dummy die, a ceramic dummy die, or other suitable materials.

In some embodiments, the semiconductor device 1a may include an encapsulant 50 (or a molding compound). In some embodiments, the encapsulant 50 may be disposed on or under the surface 10s1 of the substrate 10. A portion of the surface 10s1 may be exposed by the encapsulant 50. In some embodiments, the encapsulant 50 may be disposed on or over the surface 10s2 of the substrate 10. In some embodiments, the encapsulant 50 may encapsulate the electronic component 30. In some embodiments, the encapsulant 50 may encapsulate the dam structure 42 (or dam structure 44). In some embodiments, the encapsulant 50 may be in contact with a portion of a surface 42s1 (or a lower surface) of the dam structure 42. In some embodiments, the encapsulant 50 may be in contact with a surface 42s2 (or an upper surface) of the dam structure 42. In some embodiments, the encapsulant 50 may be in contact with a surface 42s3 (or a lateral surface) of the dam structure 42.

In some embodiments, a portion 50p1 may be disposed within the opening 20. In some embodiments, the portion 50p1 may penetrate the substrate 10. In some embodiments, the dam structure 42 may cover or vertically overlap the portion 50p1 of the encapsulant 50. In some embodiments, the dam structure 44 may cover or vertically overlap the portion 50p1 of the encapsulant 50. In some embodiments, the electronic component 30 may cover or vertically overlap the portion 50p1 of the encapsulant 50.

In some embodiments, the encapsulant 50 may be made of molding material that may include, for example, a novolac-based resin, an epoxy-based resin, a silicone-based resin, or another suitable encapsulant. Suitable fillers may also be included, such as powdered SiO₂.

In some embodiments, the semiconductor device 1a may include conductive wires 60. In some embodiments, the conductive wires 60 may be configured to electrically connect the substrate 10 and the electronic component 30. In some embodiments, the conductive wires 60 may pass through the opening 20. In some embodiments, each of the conductive wires 60 may have a first terminal connected to the surface 10s1 of the substrate 10 and a second terminal connected to the active surface of the electronic component 30 (e.g., the lower surface of the electronic component 30).

In some embodiments, the conductive wires 60 may be encapsulated by the encapsulant 50. In some embodiments, the conductive wires 60 may include metal, such as copper (Cu), silver (Ag), gold (Au), nickel (Ni), aluminum (Al), alloys thereof, combinations thereof, or other suitable materials.

In some embodiments, the semiconductor device 1a may include electrical connectors 70. In some embodiments, the electrical connectors 70 may be disposed on or under the surface 10s1 of the substrate 10. The electrical connectors 70 may be configured to provide an external connection. The electrical connectors 70 may be electrically connected to an external device (e.g., a semiconductor die or a circuit board). The electrical connectors 70 may include a solder material, such as alloys of gold and tin solder or alloys of silver and tin solder.

When forming an encapsulant on a substrate, a mold chase is used to accommodate a substrate with a slot. Next, a molding material is filled into the mold chase and flows from the upper surface (e.g., the surface on which an electronic component is disposed) to the lower surface of the substrate through the slot. In a comparative device, the molding material may encroach an undesired area of the lower surface of the substrate (e.g., the area on which the solder balls are disposed), which causes a failure of an electrical connection between devices. One of the reasons causing a molding material overflowing is that a slot with a greater aperture, especially a slot with greater dimension along the X direction. In this embodiment, a dam structure is provided to reduce the area (or aperture) of the slot to prevent an undesired region of the substrate from being encroached by the encapsulant. As a result, the issues of the comparative devices can be addressed.

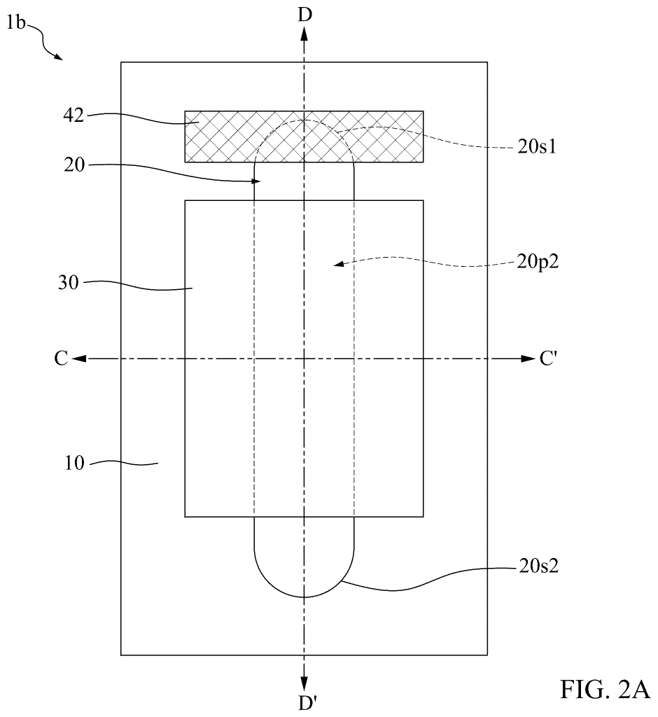

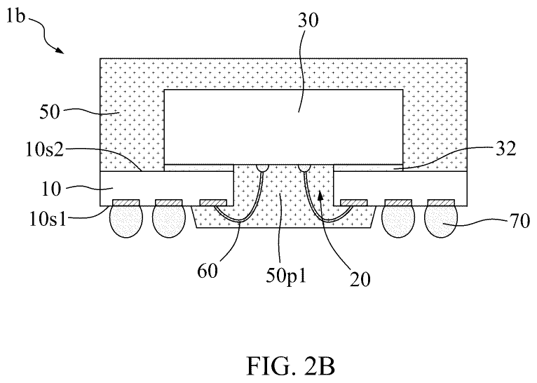

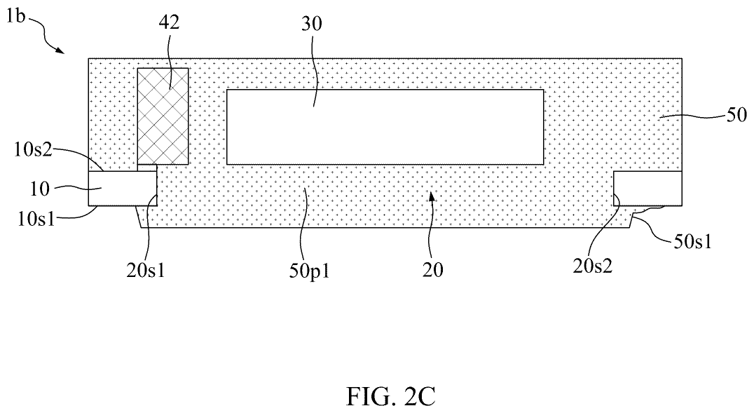

FIG. 2A, FIG. 2B, and FIG. 2C illustrate a semiconductor device 1b, in accordance with some embodiments of the present disclosure. In some embodiments, the semiconductor device 1b has a structure similar to that of the semiconductor device 1a, and one of the differences between them is that the semiconductor device 1b does not include the dam structure 44.

In some embodiments, the opening 20 may have a side 20s1 and a side 20s2 on two opposite sides of the longer edge. In some embodiments, the dam structure 42 is disposed on or at the side 20s1. In some embodiments, no dam structure is disposed on or over the side 20s2. In some embodiments, the surface roughness of a surface 50s1 (or lower surface) of the encapsulant 50 at the side 20s1 may be less than that of the encapsulant 50 at the side 20s2. In some embodiments, the encapsulant 50 may include an overflow portion on the surface 10s1 of the substrate 10 abutting the side 20s2. In some embodiments, the quantity of the electrical connectors at or abutting the side 20s2 may be less than that at or abutting the side 20s1.

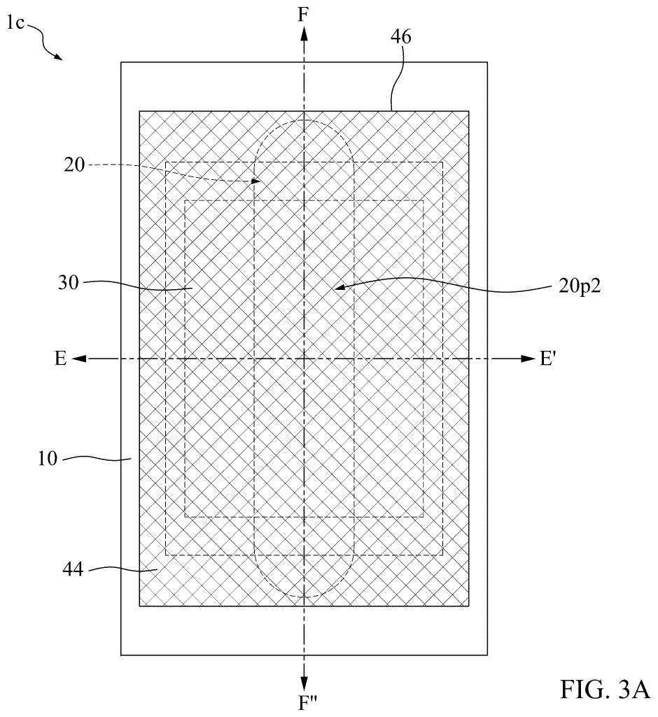

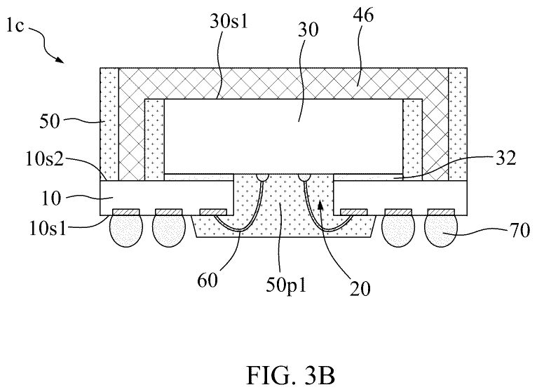

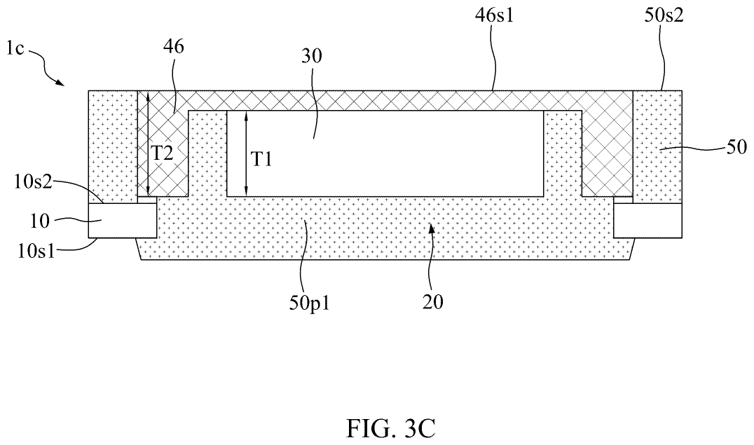

FIG. 3A, FIG. 3B, and FIG. 3C illustrate a semiconductor device 1c, in accordance with some embodiments of the present disclosure. In some embodiments, the semiconductor device 1c has a structure similar to that of the semiconductor device 1a, and one of the differences between them is that the semiconductor device 1c may include a dam structure 46.

In some embodiments, the dam structure 46 may be further configured to efficiently transmit heat from the semiconductor device 1c to the surroundings. In some embodiments, the dam structure 46 may cover a surface 30s1 (or upper surface) of the electronic component 30. In some embodiments, a surface 46s1 (or upper surface) of the dam structure 46 is substantially aligned with or coplanar with a surface 50s2 (or an upper surface) of the encapsulant 50. In some embodiments, the surface 46s1 is exposed by the encapsulant 50.

In some embodiments, the dam structure 46 may cover the central portion 20p2 of the opening 20. In some embodiments, the portion 50p1 of the encapsulant within the opening 20 may be fully covered by the dam structure 46.

In some embodiments, the dam structure 46 may include a thermally conductive material, such as copper (Cu), tungsten (W), silver (Ag), gold (Au), ruthenium (Ru), iridium (Ir), nickel (Ni), osmium (Os), rhodium (Rh), aluminum (Al), molybdenum (Mo), cobalt (Co), alloys thereof, combinations thereof or other suitable materials. In some embodiments, the dam structure 46 may include a heat sink or other suitable heat dissipating element, such as a heat pipe which includes a vapor chamber or other suitable elements.

The electronic device 30 may have a thickness T1. The dam structure 46 may have a thickness T2. In some embodiments, the thickness T2 may be greater than the thickness T1.

In some embodiments, the dam structure 46 may include one or more openings (not shown) configured to allow a molding material to pass through.

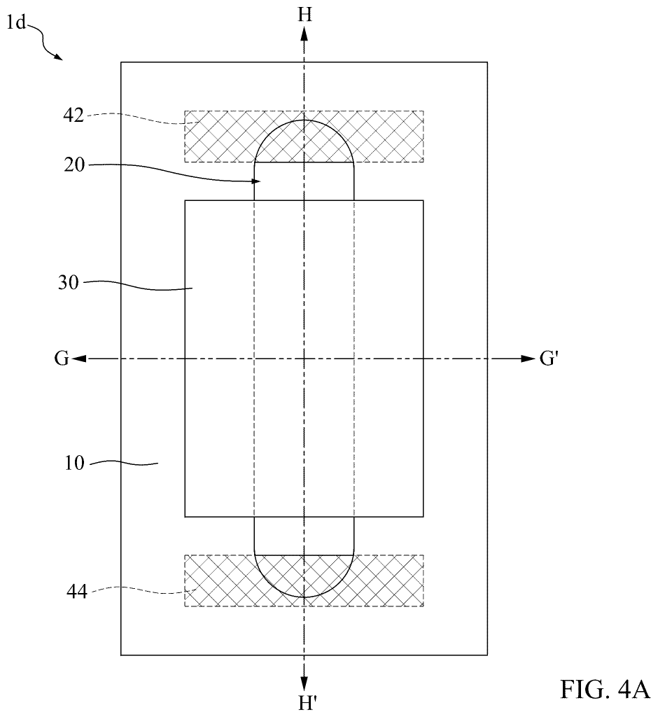

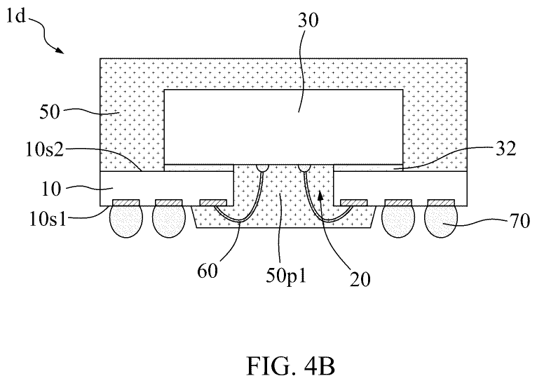

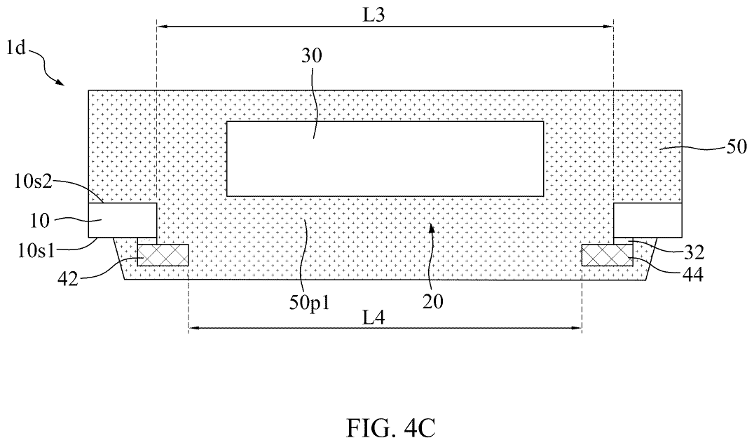

FIG. 4A, FIG. 4B, and FIG. 4C illustrate a semiconductor device 1d, in accordance with some embodiments of the present disclosure. In some embodiments, the semiconductor device 1d has a structure similar to that of the semiconductor device 1a, and one of the differences between them is that the dam structure 42 and the dam structure 44 of the semiconductor device 1d are disposed on or under the surface 10s1 of the substrate 10.

As shown in FIG. 4C, the dam structure 42 and dam structure 44 may define the opening 20 with a third length L3 at the surface 10s2 of the substrate 10 and a fourth length L4 at the surface 10s1 of the substrate 10 along the Y direction. In some embodiments, the third length L3 may be greater than the fourth length L4.

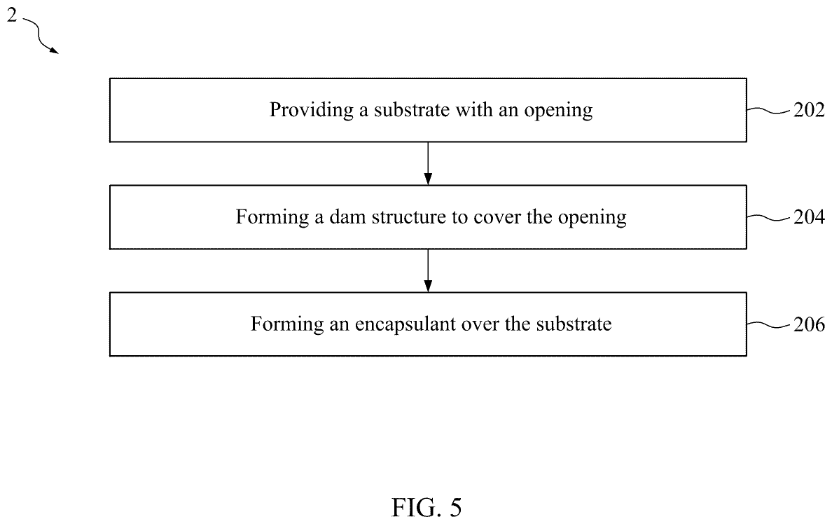

FIG. 5 is a flowchart illustrating a method 2 of manufacturing a semiconductor device, in accordance with some embodiments of the present disclosure.

The method 2 begins with an operation 202 in which a substrate may be provided. The substrate may define an opening penetrating the substrate. An electronic component may be attached to an upper surface of the substrate. Conductive wires may be formed to electrically connect a lower surface of the substrate and the electronic component. The substrate and the electronic component may define an encapsulant-injection slot with a first area.

The method 2 continues with an operation 204 in which at least one dam structure may be formed. The dam structure may be formed on the upper surface of the substrate 10. In some embodiments, the dam structure may be attached to the substrate by an adhesive material, such as a glue or other suitable materials. The substrate, the dam structure, and the electronic component may define an encapsulant-injection slot with a second area less than the first area.

The method 2 continues with an operation 206 in which an encapsulant may be formed to encapsulate the electronic component, the dam structure and the conductive wires. As a result, a semiconductor device may be produced

The method 2 is merely an example, and is not intended to limit the present disclosure beyond what is explicitly recited in the claims. Additional operations can be provided before, during, or after each operation of the method 2, and some operations described can be replaced, eliminated, or reordered for additional embodiments of the method. In some embodiments, the method 2 can include further operations not depicted in FIG. 5. In some embodiments, the method 2 can include one or more operations depicted in FIG. 5.

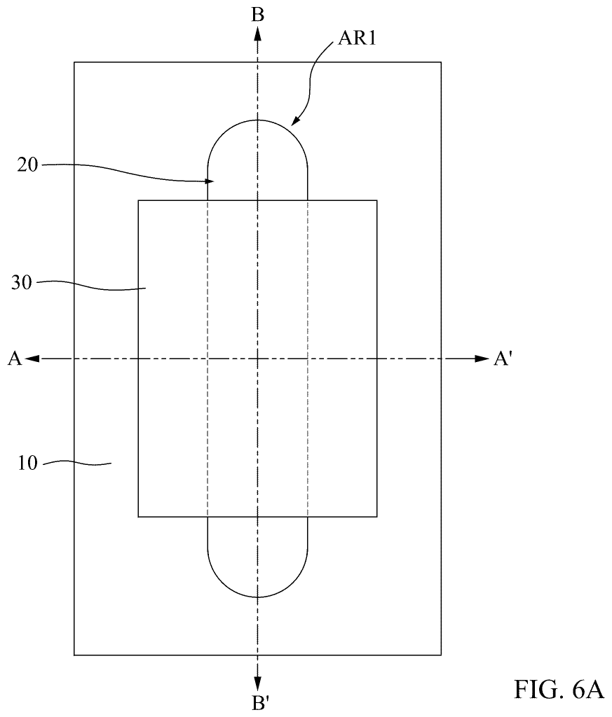

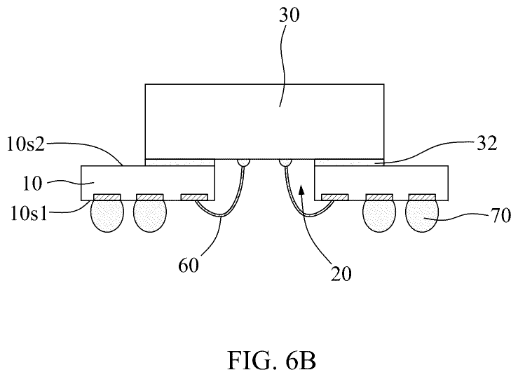

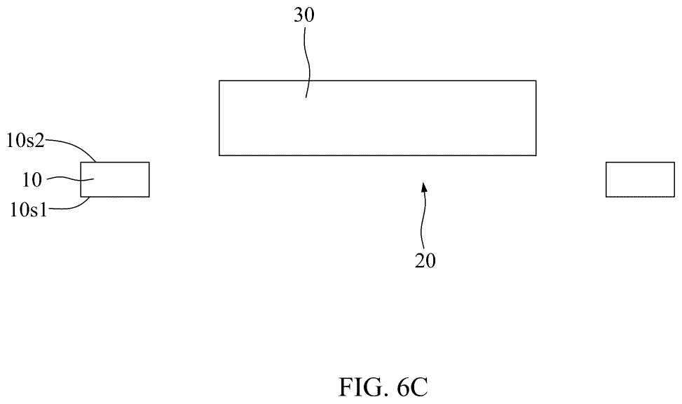

FIG. 6A-FIG. 8A illustrate one or more stages of an exemplary method for manufacturing a semiconductor device according to some embodiments of the present disclosure. FIG. 6B-FIG. 8B, and FIG. 6C-FIG. 8C are cross-sectional views along line A-A′, and B-B′ of FIG. 6A-FIG. 8A, respectively. In some embodiments, the semiconductor device 1a may be manufactured through the operations described with respect to FIG. 6A-FIG. 8A.

Referring to FIG. 6A, FIG. 6B, and FIG. 6C, the substrate 10 may be provided. The substrate 10 may define the opening 20 penetrating the substrate 10. The electronic component 30 may be attached to the surface 10s2 of the substrate 10. The conductive wires 60 may be formed to electrically connect the surface 10s1 of the substrate 10 and the electronic component 30. As shown in FIG. 6A, the opening 20 exposed by the electronic component 30 may have an area AR1.

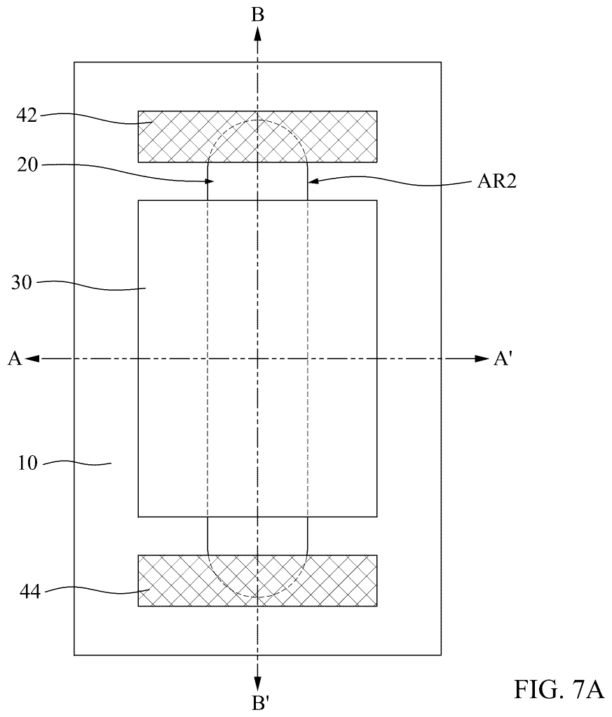

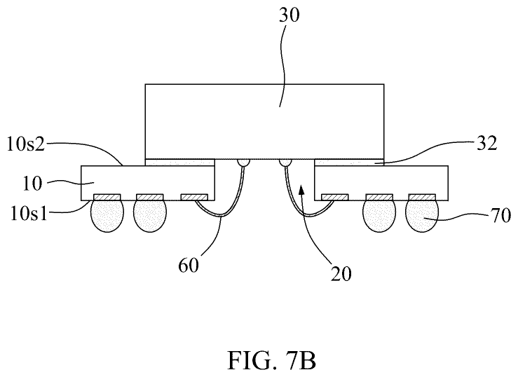

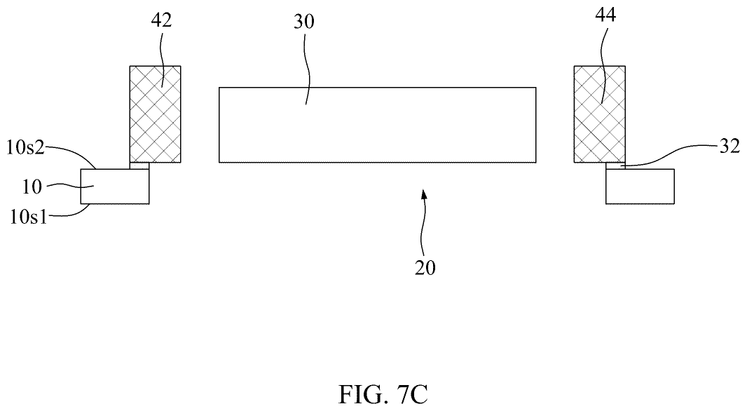

Referring to FIG. 7A, FIG. 7B, and FIG. 7C, the dam structure 42 and dam structure 44 may be formed. The dam structure 42 and dam structure 44 may be formed on the surface 10s2 of the substrate 10. In some embodiments, the dam structure 42 and dam structure 44 may be attached to the substrate 10 by an adhesive material, such as a glue or other suitable materials. In some embodiments, the opening 20 exposed by the electronic component 30 and the dam structure 42 and dam structure 44 may have an area AR2. In some embodiments, the area AR2 may be less than the area AR1.

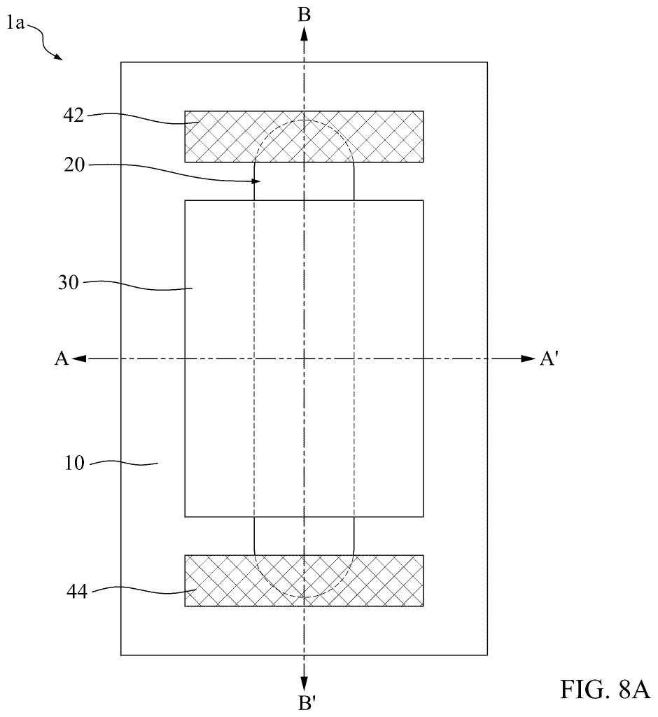

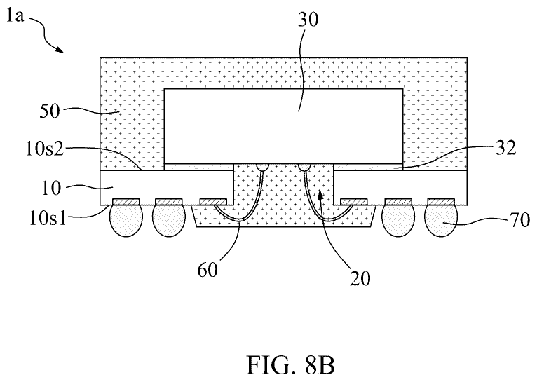

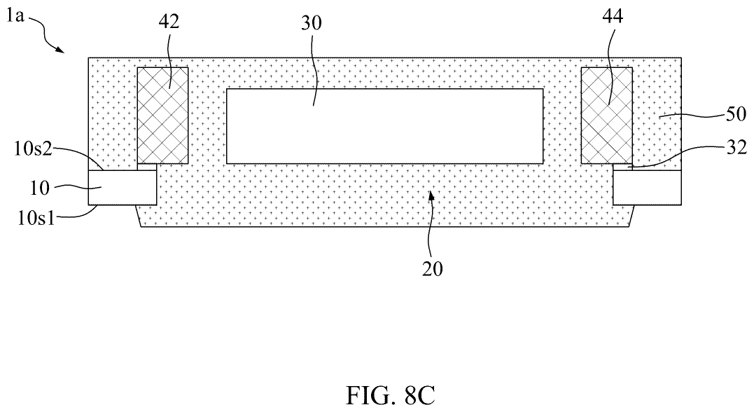

Referring to FIG. 8A, FIG. 8B, and FIG. 8C, the encapsulant 50 may be formed to encapsulate the electronic component 30, the dam structure 42, dam structure 44, and the conductive wires 60. As a result, a semiconductor device (e.g., the semiconductor device 1a) may be produced.

In this stage, if the width of the opening 20 (e.g., the width W1 as shown in FIG. 1A) is relatively large, the molding material would encroach an undesired area of the surface 10s1 of the substrate 10. In some embodiments, the dam structure 42 and dam structure 44 may be used to reduce the area (or aperture) of the opening 20 to prevent the surface 10s1 of the substrate 10 from being encroached by a molding material. As a result, the yield of manufacturing a semiconductor device can be improved.

One aspect of the present disclosure provides a semiconductor device. The semiconductor device includes a substrate, an electronic component, an encapsulant, and a dam structure. The substrate has a lower surface and an upper surface opposite to the first surface. The electronic component is disposed on the upper surface of the substrate. The encapsulant is disposed on the upper surface of the substrate and has a portion penetrating the substrate. The dam structure vertically overlaps the portion of the encapsulant.

Another aspect of the present disclosure provides another semiconductor device. The semiconductor device includes a substrate, an electronic component, an encapsulant, and a dam structure. The substrate has a lower surface and an upper surface opposite to the first surface. The electronic component is disposed on the upper surface of the substrate. The encapsulant is disposed on the upper surface of the substrate and has a portion penetrating the substrate. The substrate and the dam structure define an encapsulant-injection slot. A first aperture of the encapsulant-injection slot abutting the upper surface of the substrate is different from a second aperture of the encapsulant-injection slot abutting the lower surface of the substrate.

Another aspect of the present disclosure provides a method of manufacturing a semiconductor device. The method includes: providing a substrate having a lower surface and an upper surface opposite to the first surface, wherein the substrate defines an encapsulant-injection slot penetrating the lower surface and the upper surface; forming an electronic component on the upper surface of the substrate; forming a dam structure on the substrate to reduce an aperture of the encapsulant-injection slot; and forming an encapsulant on the substrate.

When forming an encapsulant on a substrate, a mold chase is used to accommodate a substrate with a slot. Next, a molding material is filled into the mold chase and flows from the upper surface (e.g., the surface on which an electronic component is disposed) to the lower surface of the substrate through the slot. In a comparative device, the molding material may encroach an undesired area of the lower surface of the substrate (e.g., the area on which the solder balls are disposed), which causes a failure of an electrical connection between devices. One of the reasons causing a molding material overflowing is that a slot with a greater aperture, especially a slot with greater dimension along the X direction. In this embodiment, a dam structure is provided to reduce the area (or aperture) of the slot to prevent an undesired region of the substrate from being encroached by the encapsulant. As a result, the issues of the comparative devices can be addressed.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate having a lower surface and an upper surface opposite to the first surface;
an electronic component disposed on the upper surface of the substrate;
an encapsulant disposed on the upper surface of the substrate and having a portion penetrating the substrate; and
a dam structure, wherein the substrate and the dam structure define an encapsulant-injection slot, and a first aperture of the encapsulant-injection slot abutting the upper surface of the substrate is different from a second aperture of the encapsulant-injection slot abutting the lower surface of the substrate;
wherein the encapsulant is further disposed at a first side and a second side, opposite to the first side, of the lower surface of the substrate, and a roughness of the encapsulant at the first side of the lower surface of the substrate is different from a roughness of the encapsulant at the second side of the lower surface of the substrate.

2. The semiconductor device of claim 1, wherein the dam structure is disposed on the upper surface of the substrate.

3. The semiconductor device of claim 1, wherein the dam structure is disposed on the lower surface of the substrate.

4. The semiconductor device of claim 1, wherein the dam structure comprises a dummy die.

5. The semiconductor device of claim 1, wherein the dam structure comprises a thermally conductive material.

6. The semiconductor device of claim 1, wherein the dam structure is exposed by the encapsulant.

7. The semiconductor device of claim 1, wherein the dam structure covers an upper surface of the electronic component.

8. The semiconductor device of claim 1, wherein an upper surface of the dam structure is substantially aligned with an upper surface of the encapsulant.

9. The semiconductor device of claim 1, further comprising:
a conductive wire electrically connecting the substrate and the electronic component and passing through the encapsulant-injection slot.

10. A method of manufacturing a semiconductor device comprising:
providing a substrate having a lower surface and an upper surface opposite to the first surface, wherein the substrate defines an encapsulant-injection slot penetrating the lower surface and the upper surface;
forming an electronic component on the upper surface of the substrate;
forming a dam structure on the substrate to reduce an aperture of the encapsulant-injection slot; and
forming an encapsulant on the substrate.

11. The method of claim 10, wherein the dam structure is formed on the upper surface of the substrate.

12. The method of claim 10, wherein the dam structure is formed on the lower surface of the substrate.

13. The method of claim 10, wherein the dam structure comprises a dummy die.

14. The method of claim 10, wherein the dam structure comprises a thermally conductive material.

15. The method of claim 10, wherein the dam structure is exposed by the encapsulant.

16. The method of claim 10, wherein the dam structure covers an upper surface of the electronic component.

17. The method of claim 10, wherein an upper surface of the dam structure is substantially aligned with an upper surface of the encapsulant.

18. The method of claim 10, further comprising:
forming a conductive wire passing through the opening of the substrate to electrically connect the substrate and the electronic component.
